(19) United States
(12) Patent Application Publication
(10) Pub. No.: US 2005/0135068 A1
(43) Pub. Date: Jun. 23, 2005

(54) Electronic equipment enclosure

(76) Inventor: Brian E. Huff, Collegeville, PA (US)

Correspondence Address: WEINGARTEN, SCHURGIN, GAGNEBIN & LEBOVICI LLP, TEN POST OFFICE SQUARE, BOSTON, MA, 02109, US

(21) Appl. No.: 10/816,030

(22) Filed: Apr. 1, 2004

Related U.S. Application Data
(60) Provisional application No. 60/530,216, filed on Dec. 17, 2003.

(51) Int. Cl. H05K 5/00

(52) U.S. Cl. 361/724; 361/725; 248/917

(57) ABSTRACT

An equipment housing for passive or active electronic equipment includes a back box and a front enclosure that is mounted to the back box via one or more hinges. The housing is suitable for mounting within a wall or against a wall. In one embodiment, the front enclosure includes a front panel and one or more drawers pivotally mounted to permit the stowage of equipment mounted in the drawer within the housing in a first pivotal orientation of the drawer and access to the equipment mounted in the drawer in a second pivotal orientation. In another embodiment, the front enclosure includes at least one frontal portion that is angled with respect to the front panel and extending outward therefrom to form ***. Equipment may be mounted to the frontal portion or a compartment. Acces so as to provide access to the front panel of the equipment. The front enclosure is pivotally mounted to the back box to provide access to equipment within the housing for purposes of wiring during installation, upgrades and service.

### CROSS REFERENCE TO RELATED APPLICATIONS

The present application claims priority of U.S. Provisional Application No. 60/530,216, titled Simplified Multi-Media Presentation System, filed Dec. 17, 2003.

### STATEMENT REGARDING FEDERALLY SPONSORED RESEARCH OR DEVELOPMENT

Not Applicable

### BACKGROUND OF THE INVENTION

The present invention pertains to a housing for electronic equipment such as passive or active audiovisual equipment, telecommunications, and data routing equipment. Housings, shelving and racks for audiovisual, telecommunications, and data routing equipment are widely used in educational and corporate settings and are available in a number of forms. Typical housings that are presently available are difficult and costly to install for a variety of reasons and result in systems that are difficult to repair, upgrade and maintain.

One type of housing that is routinely used for the mounting of electronic equipment involves a rack in which the electronic equipment is mounted horizontally. In such housings, multiple pieces of equipment may be stacked one above the other. Connections are typically made to connectors on the rear panel of the equipment and may interconnect different components within the housing. For example, with regard to audiovisual equipment, connections may also be made between the rear panel of equipment within the housing to audiovisual devices outside of the housing such as projectors, microphones, etc. In housings in which the electronic equipment is mounted horizontally, access to the rear of the equipment is often awkward during the initial installation of the system. Additionally, it is typically difficult to access the rear panels of components of the system unless the housing is free standing away from a wall or is custom built into an area, such as a closet, that allows rear access to the equipment. However, freestanding housings for electronic equipment occupy substantial floor space. Additionally, such systems often have a “rat's nest” of wiring running to and from the system. Built-in housings are costly and require substantial planning. Finally, housings in which the electronic equipment is horizontally mounted have a large footprint, which is disadvantageous if space is at a premium.

For the above reasons, it would be desirable to have an audiovisual equipment housing that may be readily installed in new construction and which also may be installed in existing construction without inordinate changes to the existing structure.

### BRIEF SUMMARY OF THE INVENTION

In accordance with the present invention, an improved housing for electronic equipment is disclosed. The housing includes a back box that can be installed during new construction or, alternatively, installed in existing construction. Additionally, the housing includes a front enclosure that is mountable to the back box or shell. The front enclosure is preferably hinged on one side to allow the front enclosure to swing away from the back box to allow for access to the rear of equipment mounted to the front enclosure. The ability to pivotally rotate the front enclosure with respect to the back box to gain access to the rear panels of equipment and components mounted within the housing facilitates wiring during the initial installation as well as the serviceability, upgradeability and maintenance of the components within the housing.

The front enclosure includes a front panel that may include one or more precut openings for a system control panel or visual display, that is mounted behind the respective openings. Alternatively, a system control panel and/or visual display may be mounted to the front of the front panel. The system control panel may comprise a LCD touch panel or any other suitable control panel and provides a graphical user interface for controlling the electronic system including the equipment contained within the housing. Additionally, the front enclosure includes one or more equipment compartments or supports for mounting electronic equipment to the front enclosure. The electronic equipment is typically mounted within one of the compartments or behind the front panel via rack mounting flanges as known in the art. Alternatively, if the equipment is not specifically adapted for rack mounting, an adapter may be employed to rack mount the electronic the equipment within the compartment or to the rear of the front panel.

The system control panel and the equipment contained within the housing can control and/or drive peripheral equipment, such as one or more display devices, speakers, lighting control systems, mechanized window treatments, projection screens, or other environmental controls.

In one embodiment, the equipment compartments or supports can be repositioned between a closed or first position in which the equipment is disposed substantially vertically within the housing and at least one second position in which the equipment is angled with respect to the front panel so that the control panel of the equipment is accessible for use. The equipment compartments or supports may be pivotally mounted within the front enclosure or otherwise mounted to permit repositioning of the compartment or support as described above.

In another embodiment, a compartment or support portion is integral with or attached to the front panel. Electronic equipment is mountable within the compartment or to the support portion via conventional rack mounting techniques. The compartment or support portion includes a generally rectangular frontal portion that is angled with respect to the front panel. An opening is formed between the upper edge of the frontal portion and the front panel to expose and provide access to the control panel(s) of the electronic equipment mounted within the compartment or support portion.

Other features, aspects and advantages of the presently disclosed electronic equipment housing will be apparent from the detailed description of the invention that follows.

### BRIEF DESCRIPTION OF THE SEVERAL VIEWS OF THE DRAWINGS

The invention will be more fully understood by reference to the detailed description of the invention in conjunction with the drawings of which:

FIG. 1 is a perspective view of one embodiment of an equipment housing in accordance with present invention shown mounted within a framed opening within a wall;

FIG. 2 is a perspective view of a back box mounted within a pre-framed opening within a wall;

FIG. 3a is a side view of a front enclosure and back box that form the housing depicted in FIG. 1;

FIG. 3b is a top view of the front enclosure and back box depicted in FIG. 1;

FIG. 4a is a front view of a second embodiment of an equipment housing in accordance with the present invention;

FIG. 4b is a side view of the equipment housing of FIG. 4a illustrating the front enclosure and the back box;

FIG. 5a is a front view of a third embodiment of an equipment housing in accordance with the present invention having a fixed frontal portion disposed at an angle with respect to the front panel of the front enclosure;

FIG. 5b is a side view of the back box and the front enclosure that form the equipment housing of FIG. 5a; and

FIG. 6 is a side view of a front enclosure for use in conjunction with the back box depicted in FIG. 2.

### DETAILED DESCRIPTION OF THE INVENTION

U.S. Provisional Application No. 60/530,216, titled “Simplified Multi-Media Audiovisual Presentation System,” filed Dec. 13, 2003 is hereby incorporated by reference.

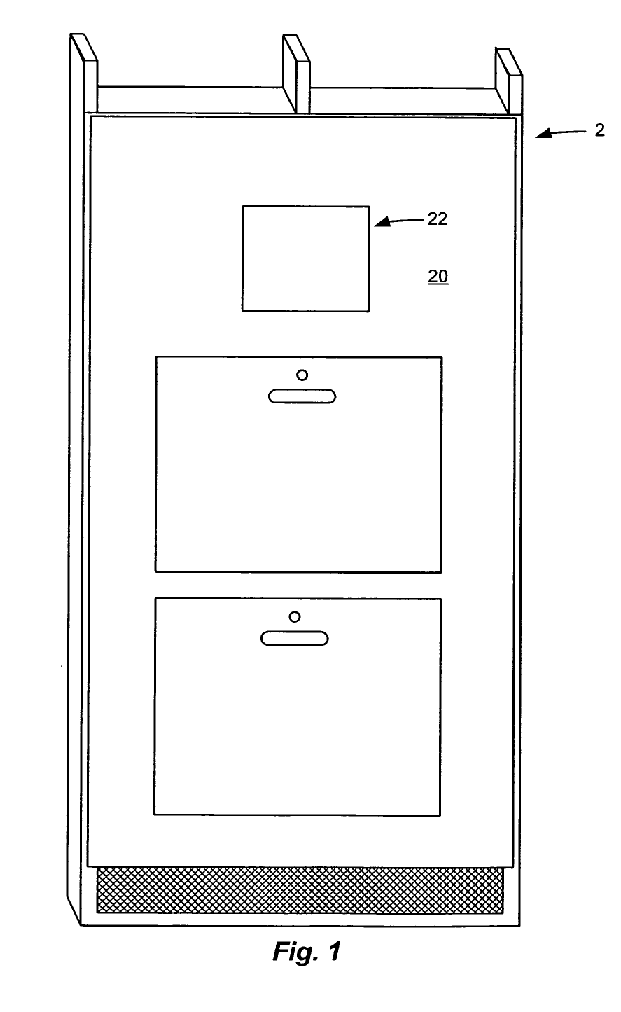

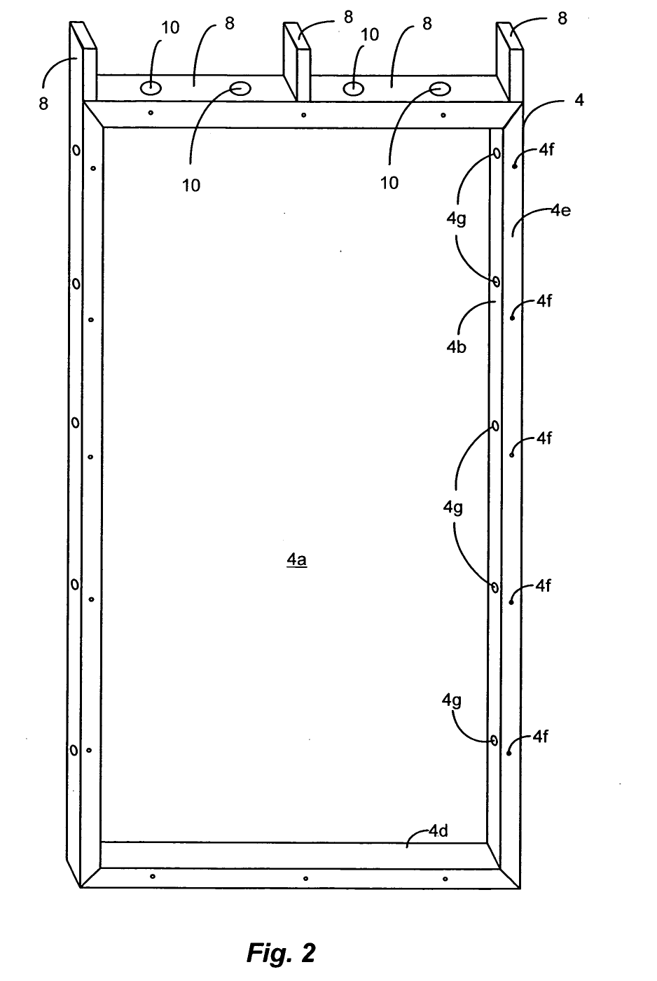

In accordance with the present invention, an electronic equipment housing for audiovisual and other passive or active electronic equipment is disclosed. Referring to FIGS. 1-3, the housing 2 (see FIG. 1) includes a back box 4 (FIG. 2) and a front enclosure 6. The back box 4 is mountable within an opening formed by framed studs 8. In a typical configuration, the back box 4 is mounted between vertical studs 8 located on approximately 32-inch or two 16-inch centers. Horizontal studs 8 define the top and bottom of the opening in which the back box 4 is situated. The back box 4 may be mounted within the opening formed by framed studs 8 during new construction or alternatively, existing framing may be modified to form an appropriate opening to accommodate the back box 4. When the housing is intended for substantially flush mounting within a wall, the back box 4 has a depth that is less than the depth of the studs; e.g. 4″, 6″, 8″, 10″ etc. depth as applicable. The housing may have a depth that is greater that the depth of the framing studs in which case a portion of the housing will extend beyond the wall surface. In this type of installation, a portion of the housing is recessed within the framed opening and a portion of the housing extends outward of the wall surface. Additionally, the housing may be mounted with the rear panel of the back box 4 flush with the wall surface.

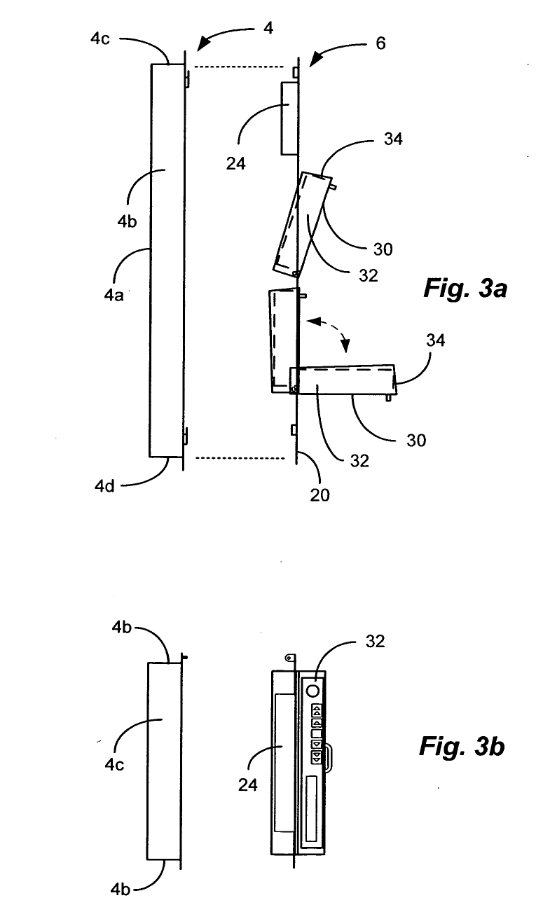

The back box 4 includes a rear panel 4a, side walls 4b, a top wall 4c (FIG. 3a), a bottom wall 4d and an outer lip 4e. The lip 4e includes front and rear surfaces and the rear surface of the lip 4e abuts the framing studs 8 when the back box 4 is disposed within the opening formed by the framing studs 8. Openings 4f are provided in the lip 4e or the side walls 4b for fasteners, such as nails or screws, that may be employed to secure the back box 4 within the framed opening.

Openings 4g may be provided in the side walls 4b or top wall 4c to allow for the entry and exit of conduit and/or wiring that connects to the equipment within the housing 2. The size of the openings is specified to accommodate all conduit, wires, plugs, and connectors that are required to pass through the respective openings. Corresponding openings are provided in the framing studs 8, which align with respective openings 4g in the side walls 4b to permit the conduit and/or wiring to enter and exit the back box 4. Additionally, openings 10 are provided through the upper cross stud and through the top wall 4c of the back box 4. The openings 10 may be used for entry and exit of wiring or for ventilation of the housing 2. Depending upon the heat output of the equipment contained within the housing 2, the housing may be convection cooled, or, alternatively, fans may be employed for forced air cooling of the equipment contained within the housing 2.

The front enclosure 6 includes a front panel 20 that is generally sized to cover the front of the back box 4. A system control panel 24 such as a touch panel, pen-based input panel or other video or computer monitor or visual display screen (FIG. 3a, 3b) is mounted to the front panel 20 such that the system control 24 is viewable and accessible through the opening 22 (FIG. 1) within the front panel 20. Alternatively, the system control panel and/or visual display screen may be mounted to the front of the front panel 20. The system control panel 24 provides the graphical user interface for control of the electronic equipment contained within the housing 2 and other electronic equipment connected to the equipment within the housing 2. Depending upon the specific equipment contained within the housing 2 and other equipment employed within the system, the system control panel may be used to control some or all of the equipment.

One or more tilt-out drawers 30 having a frontal portion are mounted to the front enclosure 6. The drawers 30 may be pivoted between a generally vertical orientation and at least one other orientation in which the upper edge of the frontal portion of the drawer 30 is spaced outboard of the front panel 20 by a predetermined distance. When the drawer 30 is pivoted outward from the front panel 20, an opening is formed between the upper edge of the frontal portion and the front panel 20. The drawers 30 may comprise compartments having a top wall, a bottom wall and side walls, or, alternatively, a bottom wall and side walls. In a preferred embodiment, the electronic equipment is mountable within drawers using conventional rack mounting hardware or adapters that adapt the equipment for rack mounting.

The drawers 30 are provided with stops to allow the drawers 30 to be tilted to predetermined angular positions with respect to the front panel 20. More specifically, stops may be provided to permit the drawers 30 to be pivoted so that the equipment control panels 34 of the equipment 32 mounted within the respective drawers 30 are accessible, as illustrated in FIGS. 3a and 3b. Additionally, a stop may be provided so that the drawers 30 may be pivotally rotated to a horizontal position generally perpendicular to the front panel 30 as illustrated in the lower drawer 30 position shown in FIG. 3a.

By way of example, audiovisual source equipment such as a VCR and/or DVD player 32, a tape player or any other suitable electronic equipment may be affixed to the drawer 30 such that the equipment control panel 34 of the source equipment 32 is accessible when the drawer 30 is pivoted as illustrated in FIG. 3a.

Electronic Industries Alliance (EIA) rack mountable equipment may be disposed within an EIA standard rack that is mounted within one of the drawers 30 of the front enclosure. Alternatively, EIA rack mountable equipment may be physically mounted to the inside surface of the front panel 20 or the rear panel 4a. Mounting of an EIA standard rack to the tilt-out drawer 30 permits ready access to rack mountable equipment disposed therein for purposes of service, upgrades and the like. Moreover, any suitable electronic equipment other than EIA rack mountable equipment may be employed.

Equipment that need not be accessed on a regular basis, such as a system switcher, power amplifier and control system, may be mounted in one of the tilt-out drawers 30 or alternatively, may be mounted behind the front panel 20 of the front enclosure 6 and accessed from the rear of the front panel 20.

To provide ready access to the equipment contained within the housing 2, the front enclosure 6 is pivotably mounted to the back box 4 via a fixed or detachable hinge. In one embodiment, a detachable hinge, such as a pintel hinge is employed to rotatably couple the front enclosure to the back box 4. The use of a detachable hinge allows the back box 4 to be installed in the roughed out framing during the construction phase. The electronic equipment may be mounted to the front enclosure 6 and the assembled front enclosure can then be mounted to the back box 4 by coupling the cooperative hinge components.

A latch and/or locks (not shown) may be provided to secure the front enclosure 6 in a closed position with respect to the back box 4. In the event of a need to service or maintain components within the housing, or in the event modifications to system wiring become necessary, the front enclosure 6 may be pivoted open to fully expose the internal wiring, components and electronic equipment contained within the housing 2. Additionally, the front enclosure 6 may be readily detached from the back box 4 by lifting the front enclosure 6 upward to disengage the upper portion of the pintel hinge that is affixed to the front panel 20 from the lower portion of the pintel hinge that is affixed to the back box 4.

The back box 4 may be fabricated without the lip 4e and lower portion of the detachable hinges may be fastened to the inside or outside surface of the side walls 4b. This configuration may be preferable when the housing 2 is intended for mounting against a wall with the rear panel 4a abutting the wall.

Cutouts or openings (not shown) may be provided in the rear panel 4a to accommodate wiring when the rear panel of the back box 4 is mounted against a wall.

In one configuration, the distance between the front panel and the rear panel is less than 4, 6, 8 or 10 inches depending on the depth of the framing and the distance between the side panels is less that 29 inches to permit mounting of the back box between a pair of framing studs spaced on 32 inch centers. Thus, to obtain a desired footprint that is relatively shallow, one embodiment of the presently disclosed housing maintains a ratio of the width between the side walls over the distance between the front and rear panels (depth of the back box) that is greater than 3.0. This ratio assures that the housing will fit within the framed wall within studs on 32-inch centers or two 16-inch centers.

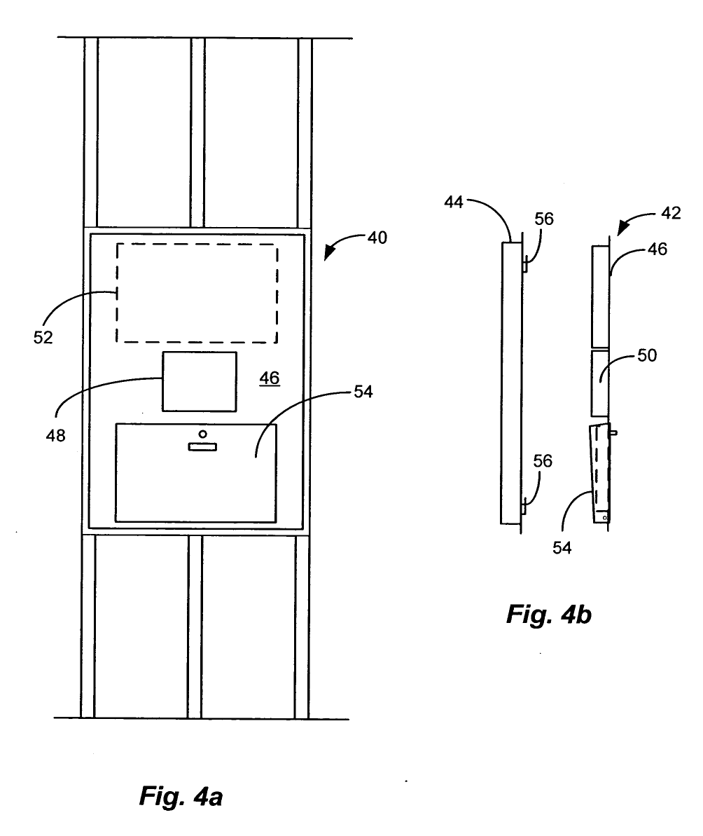

A second housing configuration in accordance with the present invention is depicted in FIGS. 4a and 4b. The housing 40 includes a front enclosure 42 and a back box 44 configured for mounting within a pre-framed opening within a wall. As illustrated in FIGS. 4a and 4b, the housing 40 in intended for mounting generally in the middle of a wall. The front enclosure 42 includes a front panel 46 having an opening 48 therethrough. A system control panel 50 is mountable to the back surface of the front panel 46 and is accessible through the opening 48. Alternatively, the system control panel may be mounted to the front surface of the front panel. EIA rack equipment 52 or any other suitable equipment is mounted to the back surface of the front panel 46 to accommodate rack mountable equipment. A tilt-out drawer 54 is provided to allow audiovisual or other electronic devices to be mounted vertically within a housing having a shallow depth. Mounting of the equipment within the housing in this manner does not require the depth that would be needed to accommodate horizontal mounting of the equipment. The tilt-out drawer 54 is pivotally mounted to the front enclosure 42 as discussed above in connection with FIGS. 1-3. The drawer 54 may therefore be pivoted toward a user such that the equipment control panel on the front of equipment mounted to the drawer 54 is accessible for use. The front enclosure 42 is detachably mountable to the back box 44 via a hinges 56, such as pintel hinges to permit the front enclosure to be removed for access, service and/or maintenance to the wiring and equipment within the housing.

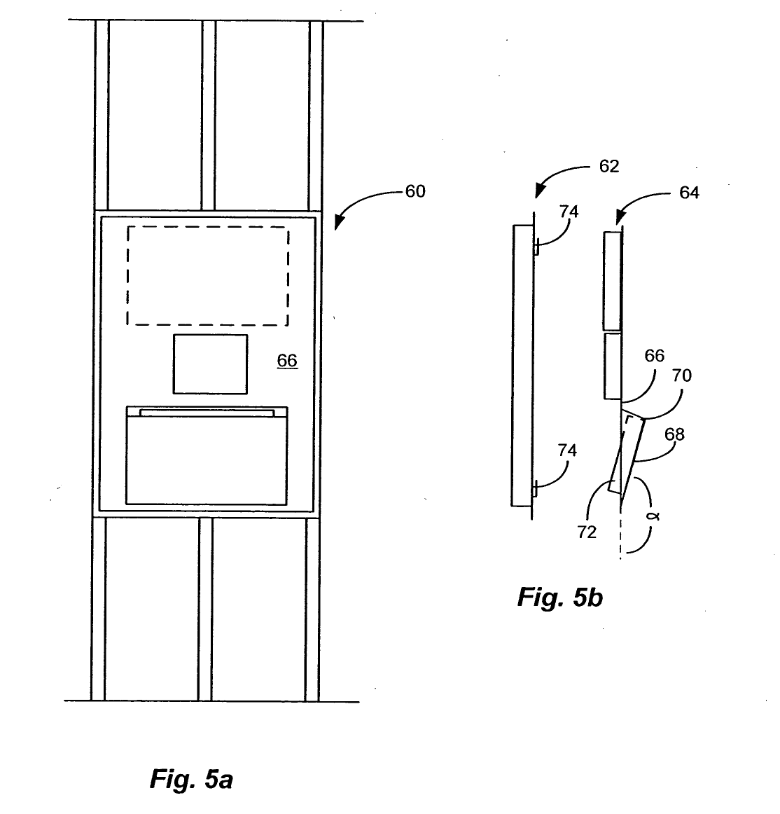

FIGS. 5a and 5b depict another embodiment of a housing 60 in accordance with the present invention. The housing 60 includes a back box 62 and a front enclosure 64 having a front panel 66. The housing 60 generally is similar to the housing 50 discussed above in connection with FIGS. 4a and 4b; however, the front enclosure 64 includes a frontal portion 68 that is fixedly positioned with respect to the front panel 66 and angled at an obtuse angle α with respect to the front panel 66. The frontal portion 68 includes an upper edge 70 that is spaced from the front panel 66 to provide access to the equipment control panel of equipment 72 mounted to the frontal portion 68.

The front enclosure 64 is mounted to the back box 62 via hinges 74 and may be pivoted to open the housing 60 and to obtain access to the rear panel of the equipment 72 mounted to the support portion 68.

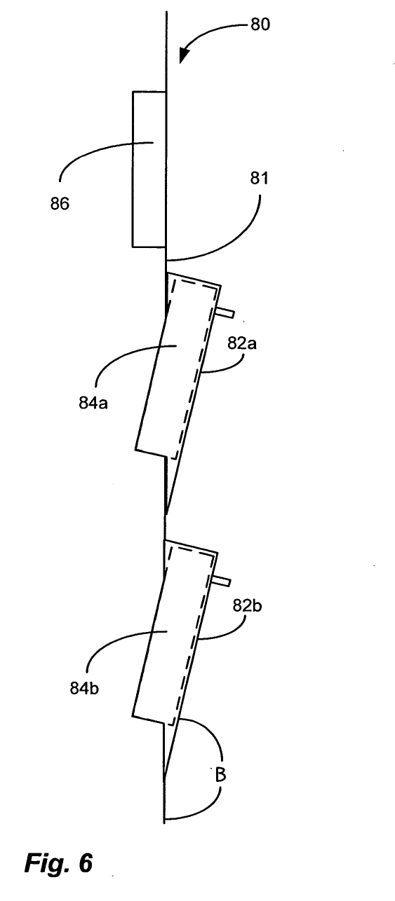

FIG. 6 depicts a side view of a front enclosure 80 that is sized and configured for mating with the back box 4 depicted in FIG. 2. The front enclosure 80 includes a front panel 81. In the illustrated embodiment, the front enclosure 80 includes upper and lower frontal portions 82a and 82b respectively that extend from the front panel 81 at obtuse angles α and β respectively. The angles may have different values or may be the same depending upon specific design considerations. Audiovisual or other electronic equipment 84a, 84b may be mounted to the frontal portions 82a and 82b via conventional rack mounting hardware while providing access to the equipment control panels for the respective equipment. A system control panel 86 is mounted to the rear surface of the front panel 81 and is accessible through an opening (not visible) in the front panel 81. Alternatively, the system control panel 86 is mounted to the front surface of the front panel 81.

The ratio of the width between the side walls to the front to back depth discussed above in connection with FIG. 1 may be employed with the subsequently disclosed embodiments to maintain a shallow footprint for in-wall mounting or mounting of the equipment housing against a wall.

While typical equipment housings for audiovisual systems will contain one or more playback, playback/recorder or signal source devices such as a Compact Disk player, a CD-Rom, a DVD player, a Video Cassette Recorder (VCR), a TV tuner or a personal computer, the housing may contain any appropriate type of electronic equipment. By way of example and not limitation, the housing may contain system devices such as an audio amplifier, a software programmable control system, audio, telecommunications, data and video routing and/or switching devices. The system control panel may be employed to provide a pre-configured unified user interface for control of one or more of the electronic devices.

A latch and locking mechanism may be provided to secure and/or lock the front enclosure to the back box in each of the disclosed embodiments to prevent unauthorized access to the components within the housing.

It will be apparent to those of ordinary skill in the art that modifications to and variations of the above described equipment housing may be made without departing from the inventive concepts disclosed herein. Accordingly, the invention is not to be viewed as limited except by the scope and spirit of the appended claims.

1. An equipment housing comprising:
a back box having opposing side walls and top and bottom walls, said opposing side walls and said top and bottom walls defining a frontal opening;
a front enclosure including a front panel, said front panel having a first horizontal axis and a vertical axis passing through a plane defined by said front panel, said front enclosure being pivotably coupled to said back box; and
at least one generally rectangular frontal portion intersecting said front panel along a line generally parallel to said horizontal axis, said frontal portion intersecting said front panel at a predetermined angle in a first frontal portion position, said frontal portion having an upper edge spaced from said front panel by a first distance at said first frontal portion position to form an opening between said upper edge and said front panel.

2. The equipment housing of claim 1 further including at least one of a system control panel and a visual display screen mounted to said front panel.

3. The equipment housing of claim 2 wherein said at least one of said system control panel and said visual display is mounted behind said front panel and said front panel includes an opening sized and positioned to allow the viewing of said at least one of said system control panel and a visual display mounted to said front panel behind said opening.

4. The equipment housing of claim 2 wherein said at least one of said system control panel and said visual display screen is mounted to the front of said front panel.

5. The equipment housing of claim 2 wherein said system control panel comprises at least one of a touch screen, a pen-based input panel and a visual display screen.

6. The equipment housing of claim 1 further including at least one piece of electronic equipment having an equipment control panel, said at least one piece of electronic equipment being mounted to said front enclosure with said equipment control panel accessible through said opening between said upper edge of said frontal portion and said front panel.

7. The equipment housing of claim 6 wherein said electronic equipment includes at least one of a compact disk player, a compact disk player/recorder, a DVD player, a. DVD player/recorder, a video player, a video player/recorder, an audio player, an audio player/recorder, an AM/FM tuner, a TV tuner, an audio mixer, an audio router, a personal computer, an audiovisual switcher, an audiovisual router, a telecommunications hub, a data hub, and a telecommunications switch.

8. The equipment housing of claim 6 wherein said first distance is specified such that said equipment control panel is accessible through said opening between said upper edge of said frontal portion and said front panel when said electronic equipment is mounted to said front enclosure.

9. The equipment housing of claim 1 wherein said front enclosure is pivotally connected to said back box with a hinge to permit rotation of said front panel around an axis parallel to said vertical axis.

10. The equipment housing of claim 9 wherein said hinge is a piano hinge.

11. The equipment housing of claim 8 wherein said hinge comprises at least two hinges each having first and second detachable hinges.

12. The equipment housing of claim 11 wherein said at least two hinges are pintel hinges.

13. The equipment housing of claim 1 further including an electronic equipment rack mounted behind said front panel.

14. The equipment housing of claim 1 further including at least one electronic equipment rack mounted to said front enclosure such that said equipment rack is accessible through said opening between said upper edge of said frontal portion and said front panel.

15. The equipment housing of claim 1 wherein the distance between said opposing side walls is less than or equal to 30.5 inches.

16. The equipment housing of claim 1 wherein said back box has a width and a depth wherein the ratio of the width to the depth is greater than 3.0.

17. The equipment housing of claim 1 wherein said back box has a peripheral front edge extending along said side walls, said top wall and said bottom wall, said peripheral front edge defining a front edge plane, and said back box including a lip extending outward along at least a portion of said peripheral front edge within said front edge plane.

18. The equipment housing of claim 1 further including a pivot mechanism configured to permit pivotal rotation of said frontal portion around a second horizontal axis parallel to said first horizontal axis so as to permit said first distance to be varied as a result of the pivotal rotation of said frontal portion with respect to said front panel.

19. The equipment housing of claim 18 wherein said pivot mechanism includes a pair of pivot pins.

20. The equipment housing of claim 18 wherein said pivot mechanism includes a first hinge.

21. The equipment housing of claim 18 further including at least one mechanical stop operative to permit said frontal portion to be movably engaged at at least one predetermined rotational position with respect to said front panel.

22. The equipment housing of claim 18 wherein said at least one frontal portion is rotatable between a closed position in which said frontal portion is substantially vertical and parallel to said front panel and said first frontal portion position.

23. The equipment housing of claim 18 wherein said at least one frontal portion is rotatable to and positionable at a closed position in which said frontal portion is substantially vertical and parallel to said front panel, said first frontal portion position and a second substantially horizontal frontal portion position in which said frontal portion is generally horizontal and perpendicular to said front panel.

24. The equipment housing of claim 18 further including at least one of a system control panel and a visual display screen mounted to said front panel.

25. The equipment housing of claim 24 wherein said at least one of said system control panel and said visual display is mounted behind said front panel and said front panel includes an opening sized and positioned to allow the viewing of said at least one of said system control panel and a visual display mounted to said front panel behind said opening.

26. The equipment housing of claim 24 wherein said at least one of said system control panel and said visual display screen is mounted to the front of said front panel.

27. The equipment housing of claim 24 wherein said system control panel comprises at least one of a touch screen, a pen-based input panel and a visual display screen.

28. The equipment housing of claim 18 further including at least one piece of electronic equipment having an equipment control panel, said at least one piece of electronic equipment being mounted to said front enclosure such that said equipment control panel is accessible through said opening between the upper edge of said frontal portion and said front panel.

29. The equipment housing of claim 28 wherein said at least one piece of electronic equipment includes at least one of a compact disk player, a compact disk player/recorder, a CD-Rom, a DVD player, a DVD player/recorder, a video player, a video player/recorder, an audio player, an audio player/recorder, an AM/FM tuner, a TV tuner, an audio mixer, an audio router, a personal computer, an audiovisual switcher, an audiovisual router, a telecommunications hub, a data hub, and a telecommunications switch.

30. The equipment housing of claim 28 wherein said first distance is specified such that said equipment control panel is accessible through said opening between said upper edge of said frontal portion and said front panel when said at least one piece of electronic equipment is mounted to said front enclosure.

31. The equipment housing of claim 18 wherein said front enclosure is pivotally coupled to said back box to permit rotation of said front panel around an axis parallel to said vertical axis.

32. The equipment housing of claim 31 wherein said front enclosure is pivotally coupled to said back box with a piano hinge.

33. The equipment housing of claim 18 wherein said front enclosure is removably coupled to said back box with at least two detachable hinges.

34. The equipment housing of claim 33 wherein said detachable hinges are pintel hinges.

35. The equipment housing of claim 18 further including an electronic equipment rack mounted to the rear surface of said front panel.

36. The equipment housing of claim 18 further including an electronic equipment rack mounted to said front enclosure such that said equipment rack is accessible through said opening between said upper edge of said frontal portion and said front panel when said frontal portion is positioned at said first frontal portion position.

37. The equipment housing of claim 18 wherein the distance between said opposing side walls is less than or equal to 30.5 inches.

38. The equipment housing of claim 18 wherein said back box has a width and a depth wherein the ratio of the width to the depth is greater than 3.0.

39. The equipment housing of claim 17 wherein said back box has a peripheral front edge extending along said side walls, said top wall and said bottom wall, said peripheral front edge defining a front edge plane, said back box including a lip extending outward along at least a portion of said peripheral front edge within said front edge plane.

40. A method for installing an electronic equipment enclosure comprising the steps of:
framing a wall area to provide an opening within the framing of a predetermined height and width;
mounting a back box of a predetermined height and width less than said opening height and width respectively, within said opening said framing, wherein said back box includes a first pair of detachable hinge portions affixed to the back box; and
pivotably coupling a front enclosure having a second pair of detachable hinge portions affixed to said front enclosure to said back box by engaging said second hinge portions with said first hinge portions to permit pivotal rotation of said front enclosure with respect to said back box.

41. The method of claim 40 further including the step of mounting at least one piece of electronic equipment to said front enclosure prior to said pivotably coupling step.
